(19) United States
(12) Patent Application Publication
(10) Pub. No.: US 2018/0063616 A1
(43) Pub. Date: Mar. 1, 2018

(54) MICROELECTROMECHANICAL MICROPHONE PACKAGE STRUCTURE

(71) Applicant: LINGSEN PRECISION INDUSTRIES, LTD., Taichung City (TW)

(72) Inventors: Hsien-Ken LIAO, TAICHUNG CITY (TW); Ming-Te TU, TAICHUNG CITY (TW); Jyong-Yue TIAN, TAICHUNG CITY (TW); Yao-Ting YEH, TAICHUNG CITY (TW)

(21) Appl. No.: 15/335,697

(22) Filed: Oct. 27, 2016

(30) Foreign Application Priority Data
Aug. 29, 2016 (TW) 105127661

(51) Int. Cl. H04R 1/04; H04R 19/04; B81B 7/00

(52) U.S. Cl. CPC H04R 1/04; H04R 19/04; B81B 2207/012; H04R 2201/003; B81B 2201/0257; B81B 7/007

(57) ABSTRACT

A microelectromechanical microphone package structure includes a substrate, sidewall, lid, sound wave transducer and processing module. The substrate has a plate, sound aperture penetrating the plate, and conduction portion disposed on the plate. The sidewall has one end disposed on the plate and has a conduction circuit electrically connected to the conduction portion. A chamber is defined between the lid, sidewall and plate. The lid has at least one solder pad and a third contact in electrical conduction with each other. The third contact is electrically connected to the conduction circuit. The sound wave transducer is disposed on the plate and in the chamber and aligned with the sound aperture. The processing module, which is disposed on the plate and in the chamber and electrically connected to the sound wave transducer and conduction portion, includes a processing chip and electronic component which are stacked and disposed on the plate.

### BACKGROUND OF THE INVENTION

### Field of the Invention

The present invention relates to chip packages and, more particularly, to a microelectromechanical microphone package structure.

### Description of the Prior Art

Microelectromechanical systems (MEMS) are characterized in that various electronic, electrical or mechanical functions are concurrently integrated into a micro device or component by a semiconductor process or any other microprecision technology. Therefore, microelectromechanical microphones advantageously consume less power but are more compact and capable of suppressing interference with the surroundings in terms of, for example, temperature changes and electromagnetic interference than conventional assembled electret condenser microphones (ECM), and thus microelectromechanical microphones have increasingly broad applications in electro-acoustics. However, commercially-available microelectromechanical microphones feature only integration of a sound wave transducer and an application-specific integrated circuit (ASIC) into a package structure. As a result, commercially-available microelectromechanical microphones have limited functions and thus fail to meet specific user needs. Moreover, in an attempt to meet specific user needs and augment competitive advantages, manufacturers resort to improving the chip design of the application-specific integrated circuit (ASIC) and the sound wave transducer, thereby incurring high costs.

Accordingly, conventional microelectromechanical microphones have the aforesaid drawbacks and thus still have room for improvement.

### SUMMARY OF THE INVENTION

It is an objective of the present invention to provide a microelectromechanical microphone package structure whereby the microelectromechanical microphone is not only multifunction and thus meets specific user needs, but also incurs low manufacturing costs.

The microelectromechanical microphone package structure comprises a substrate, a sidewall, a lid, a sound wave transducer and a processing module. The substrate has a plate, a sound aperture and a conduction portion. The sound aperture penetrates the plate. The conduction portion is disposed on the plate. The sidewall has one end disposed on a top side of the plate. The sidewall has a conduction circuit. The conduction circuit is electrically connected to the conduction portion. The lid is connected to another end of the sidewall to form a chamber between the lid, the sidewall and the plate. The lid has at least one solder pad and a third contact which are in electrical conduction with each other. The third contact is electrically connected to the conduction circuit. The sound wave transducer is disposed on the top side of the plate and corresponds in position to the sound aperture. The sound wave transducer is disposed in the chamber. The processing module is disposed on the top side of the plate and in the chamber. The processing module is electrically connected to the sound wave transducer and the conduction portion. The processing module comprises a processing chip and an electronic component. The processing chip and the electronic component are stacked and disposed on the top side of the plate.

Preferably, the processing chip is an application-specific integrated circuit (ASIC).

Preferably, the electronic component is an active component, a passive component, or a combination thereof.

Accordingly, electronic components of different functions and types can be disposed in the microelectromechanical microphone package structure to meet specific user needs. Furthermore, unlike the prior art which resorts to improving the chip design of the processing chip and the sound wave transducer in an attempt to meet specific user needs, the present invention meets specific user needs and incurs low costs by changing electronic components of different functions and types.

Fine structures and features of the present invention are described below with reference to preferred embodiments of the present invention. However, persons skilled in the art understand that the description and preferred embodiments are illustrative of the present invention rather than restrictive of the scope of the claims of the present invention.

### BRIEF DESCRIPTION OF THE DRAWINGS

FIG. 1 is a cross-sectional view of a microelectromechanical microphone package structure according to the first preferred embodiment of the present invention, showing that a processing chip is electrically connected to an electronic component by a wire bonding process;

FIG. 2 is a cross-sectional view of the microelectromechanical microphone package structure according to the first preferred embodiment of the present invention, showing that the processing chip is electrically connected to the electronic component by a flip-chip process;

FIG. 3 is a cross-sectional view of the microelectromechanical microphone package structure according to the second preferred embodiment of the present invention, showing that the electronic component and the processing chip in FIG. 1 have swapped their stacking positions; and

FIG. 4 is a cross-sectional view of the microelectromechanical microphone package structure according to the first preferred embodiment of the present invention, showing that the microelectromechanical microphone package structure is connected to an external circuit.

### DETAILED DESCRIPTION OF THE EMBODIMENT OF THE INVENTION

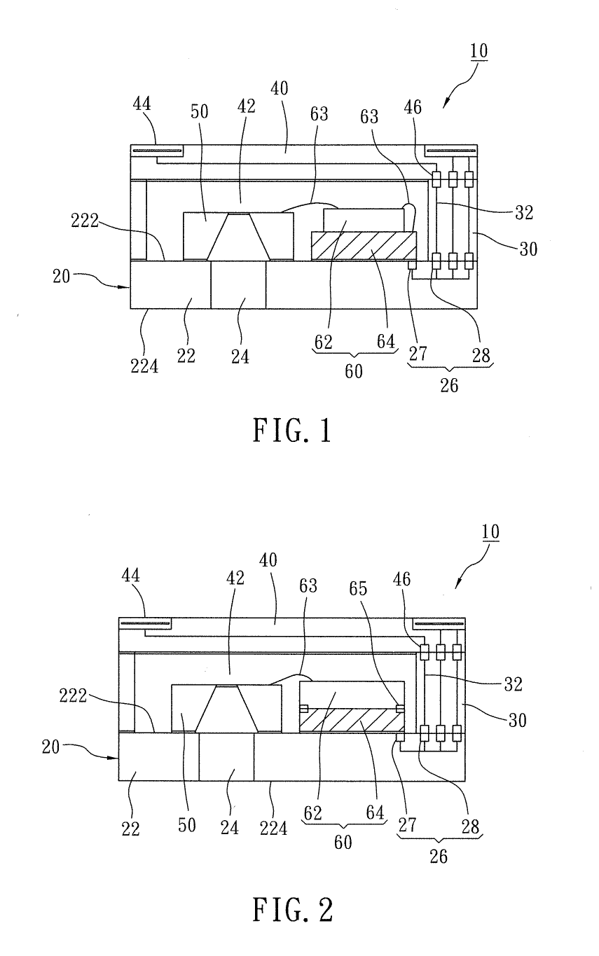

Referring to FIG. 1, a microelectromechanical microphone package structure 10 provided in the first preferred embodiment of the present invention comprises a substrate 20, a sidewall 30, a lid 40, a sound wave transducer 50 and a processing module 60.

The substrate 20 has a plate 22, a sound aperture 24 and a conduction portion 26. The plate 22 has a top side 222 and a bottom side 224. The sound aperture 24 penetrates the top side 222 and the bottom side 224 of the plate 22 and serves as a passage for sound wave. The conduction portion 26 is disposed on the plate 22 and comprises a first contact 27 and a second contact 28 which are in electrical conduction with each other.

One end of the sidewall 30 is disposed at the plate 22. Specifically speaking, one end of the sidewall 30 is disposed on the top side 222 of the plate 22. The sidewall 30 has a conduction circuit 32. The conduction circuit 32 is electrically connected to the second contact 28 of the conduction portion 26.

The lid 40 is a metal substrate, a fiberglass substrate or a ceramic substrate. The lid 40 is connected to the other end of the sidewall 30 to form a chamber 42 between the lid 40, the sidewall 30 and the plate 22. The lid 40 has at least one solder pad 44 and a third contact 46 which are in electrical conduction with each other. The third contact 46 is electrically connected to the conduction circuit 32 of the sidewall 30. The at least one solder pad 44 is provided in the plural number in another preferred embodiment.

In another preferred embodiment, the second contact 28, third contact 46 and conduction circuit 32 are provided in identical plural numbers and electrically connected, respectively. For example, three conduction circuits 32 are electrically connected to three second contacts 28 and three third contacts 46, respectively.

The sound wave transducer 50 is disposed on the top side 222 of the plate 22 and in the chamber 42. The sound wave transducer 50 corresponds in position to the sound aperture 24 so as to receive external sound wave-related signals. In this preferred embodiment, the sound wave transducer 50 converts external sound wave-related signals into electrical signals.

The processing module 60 is disposed on the top side 222 of the plate 22 and in the chamber 42. The processing module 60 is electrically connected to the sound wave transducer 50 and the conduction portion 26. The processing module 60 comprises a processing chip 62 and an electronic component 64. The electronic component 64 is disposed on the top side 222 of the plate 22 and electrically connected to the first contact 27 of the conduction portion 26 by a flip-chip process or a wire bonding process. The processing chip 62 is stacked and disposed on the electronic component 64. The processing chip 62 is electrically connected to the electronic component 64 and the sound wave transducer 50 by a wire bonding process with a metal wire 63. Referring to FIG. 2, the processing chip 62 is electrically connected to the electronic component 64 by a flip-chip process with at least one land 65.

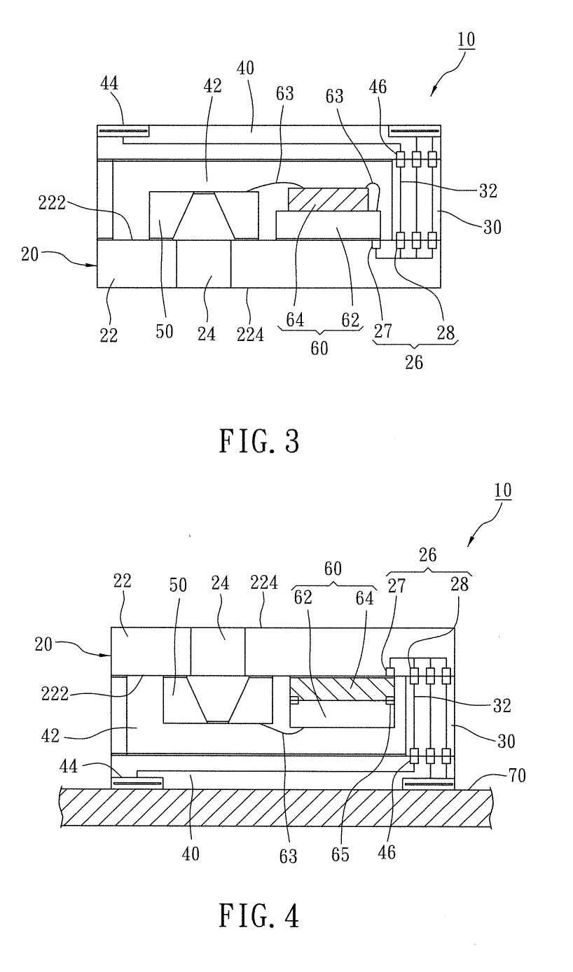

Referring to FIG. 3, in the second preferred embodiment of the present invention, the electronic component 64 and the processing chip 62 have swapped their positions; hence, the processing chip 62 is disposed on the top side 222 of the plate 22 and electrically connected to the first contact 27 of the conduction portion 26 by a flip-chip process or a wire bonding process, whereas the electronic component 64 is stacked and disposed on the processing chip 62 and electrically connected to the processing chip 62 and the sound wave transducer 50 by a wire bonding process with the metal wire 63. Alternatively, the electronic component 64 is electrically connected to the processing chip 62 by a flip-chip process.

In all the preferred embodiments of the present invention, the processing chip 62 is an application-specific integrated circuit (ASIC) designed and manufactured according to specific user needs and a specific electronic system. The processing chip 62 integrates circuits, such as a charge pump, a voltage regulator, an amplifier, a sigma delta modulator and an analog-to-digital converter, thereby achieving advantages, such as being more compact, more robust and capable of suppressing noise.

In all the preferred embodiments of the present invention, the electronic component 64 is an active component, a passive component or a combination thereof, for example, a transistor, a silicon controlled rectifier, a diode, a capacitor, a resistor, an inductor or a combination thereof to meet specific user needs. Alternatively, the electronic component 64 is an oscillator or any other microelectromechanical component.

Referring to FIG. 4, the microelectromechanical microphone package structure 10 previously shown in FIG. 2 is inverted, with the lid 40 facing downward, and the substrate 20 facing upward. As shown in FIG. 4, the sound wave transducer 50 receives external sound wave-related signals through the sound aperture 24 and converts them into electrical signals before sending the electrical signals to the processing chip 62 and the electronic component 64. After being processed by the processing chip 62 and the electronic component 64, the electrical signals are sent to at least one solder pad 44 through the conduction portion 26, conduction circuit 32 and third contact 46 and thus are ready for use by an external circuit 70.

Therefore, users can place and stack the electronic components 64 of different functions and types in the microelectromechanical microphone package structure 10 according to the surroundings and purpose, to not only meet specific user needs but also increase the functions of the microelectromechanical microphone package structure 10. Hence, the microelectromechanical microphone package structure 10 of the present invention has more functions than its conventional counterpart. Moreover, unlike the prior art which resorts to improving the chip design of the processing chip 62 and the sound wave transducer 50 in an attempt to meet specific user needs, the present invention meets specific user needs and incurs low costs by changing the electronic components 64 of different functions and types.

Constituent components and positions thereof disclosed in the above embodiments of the present invention are illustrative rather than restrictive of the scope of the present invention; hence, their replacement by equivalent components as well as their changes are intended to fall within the scope of the appended claims.

What is claimed is:

1. A microelectromechanical microphone package structure, comprising:
a substrate having a plate, a sound aperture and a conduction portion, with the sound aperture penetrating the plate and the conduction portion being disposed on the plate;
a sidewall having an end disposed on a top side of the plate and having a conduction circuit, with the conduction circuit being electrically connected to the conduction portion;
a lid connected to another end of the sidewall to form a chamber between the lid, the sidewall and the plate and having at least one solder pad and a third contact which are in electrical conduction with each other, with the third contact being electrically connected to the conduction circuit;
a sound wave transducer disposed on the top side of the plate and in the chamber and corresponding in position to the sound aperture; and
a processing module disposed on the top side of the plate and in the chamber and electrically connected to the sound wave transducer and the conduction portion, wherein the processing module comprises a processing chip and an electronic component which are stacked and disposed on the top side of the plate.

2. The microelectromechanical microphone package structure of claim 1, wherein the electronic component is disposed on the top side of the plate and electrically connected to the conduction portion by flip-chip process or wire bonding process, wherein the processing chip is stacked and disposed on the electronic component and electrically connected to the electronic component by flip-chip process or wire bonding process and electrically connected to the sound wave transducer by a wire bonding process.

3. The microelectromechanical microphone package structure of claim 1, wherein the processing chip is disposed on the top side of the plate and electrically connected to the conduction portion by flip-chip process or wire bonding process, wherein the electronic component is stacked and disposed on the processing chip and electrically connected to the processing chip by flip-chip process or wire bonding process and electrically connected to the sound wave transducer by a wire bonding process.

4. The microelectromechanical microphone package structure of claim 2, wherein the conduction portion comprises a first contact and a second contact which are in electrical conduction with each other, with the first contact electrically connected to the electronic component, and the second contact electrically connected to the conduction circuit.

5. The microelectromechanical microphone package structure of claim 3, wherein the conduction portion comprises a first contact and a second contact which are in electrical conduction with each other, with the first contact electrically connected to the processing chip, and the second contact electrically connected to the conduction circuit.

6. The microelectromechanical microphone package structure of claim 1, wherein the lid is a metal substrate, a fiberglass substrate or a ceramic substrate.

7. The microelectromechanical microphone package structure of claim 2, wherein the lid is a metal substrate, a fiberglass substrate or a ceramic substrate.

8. The microelectromechanical microphone package structure of claim 3, wherein the lid is a metal substrate, a fiberglass substrate or a ceramic substrate.

9. The microelectromechanical microphone package structure of claim 1, wherein the processing chip is an application-specific integrated circuit (ASIC).

10. The microelectromechanical microphone package structure of claim 2, wherein the processing chip is an application-specific integrated circuit (ASIC).

11. The microelectromechanical microphone package structure of claim 3, wherein the processing chip is an application-specific integrated circuit (ASIC).

12. The microelectromechanical microphone package structure of claim 1, wherein the electronic component is an active component, a passive component, or a combination thereof.

13. The microelectromechanical microphone package structure of claim 2, wherein the electronic component is an active component, a passive component, or a combination thereof.

14. The microelectromechanical microphone package structure of claim 3, wherein the electronic component is an active component, a passive component, or a combination thereof.

15. The microelectromechanical microphone package structure of claim 4, wherein the electronic component is an active component, a passive component, or a combination thereof.

16. The microelectromechanical microphone package structure of claim 5, wherein the electronic component is an active component, a passive component, or a combination thereof.

17. The microelectromechanical microphone package structure of claim 7, wherein the electronic component is an active component, a passive component, or a combination thereof.

18. The microelectromechanical microphone package structure of claim 8, wherein the electronic component is an active component, a passive component, or a combination thereof.

19. The microelectromechanical microphone package structure of claim 10, wherein the electronic component is an active component, a passive component, or a combination thereof.

20. The microelectromechanical microphone package structure of claim 11, wherein the electronic component is an active component, a passive component, or a combination thereof.
